(19) United States
(12) Patent Application Publication
(10) Pub. No.: US 2026/0255670 A1
(43) Pub. Date: Aug. 27, 2026

(54) CONTACT STRUCTURE FOR ISOLATED SOURCE/DRAIN REGION

(71) Applicant: International Business Machines Corporation, Armonk, NY (US)

(72) Inventors: Lijuan Zou, Albany, NY (US); Ruilong Xie, Niskayuna, NY (US); Tao Li, Slingerlands, NY (US); Oleg Gluschenkov, Tannersville, NY (US)

(21) Appl. No.: 19/061,198

(22) Filed: Feb. 24, 2025

(51) Int. Cl. H10D 84/85; H10D 30/00; H10D 30/01; H10D 30/43; H10D 62/10; H10D 62/13; H10D 64/23; H10D 84/01

(52) U.S. Cl. CPC H10D 84/856; H10D 30/014; H10D 30/019; H10D 30/43; H10D 30/502; H10D 62/121; H10D 62/151; H10D 64/256; H10D 84/0133; H10D 84/017; H10D 84/0186; H10D 84/851

(57) ABSTRACT

A semiconductor device includes at least two adjoining source/drain regions corresponding to at least two adjacent transistor devices, where a first one of the at least two adjoining source/drain regions is disposed between at least two isolation structures. The semiconductor device further includes an extended source/drain contact connected to the at least two adjoining source/drain regions.

### BACKGROUND

The present application relates to semiconductors, and more specifically, to techniques for forming semiconductor structures. Semiconductors and integrated circuit chips have become ubiquitous within many products, particularly as they continue to decrease in cost and size. There is a continued desire to reduce the size of structural features and/or to provide a greater amount of structural features for a given chip size. Miniaturization, in general, allows for increased performance at lower power levels and lower cost. Present technology is at or approaching atomic level scaling of certain micro-devices such as logic gates, field-effect transistors (FETs), and capacitors.

### SUMMARY

Embodiments described herein provide techniques for forming a contact structure for an isolated source/drain region.

In one embodiment, a semiconductor device includes at least two adjoining source/drain regions corresponding to at least two adjacent transistor devices, where a first one of the at least two adjoining source/drain regions is disposed between at least two isolation structures. The semiconductor device further includes an extended source/drain contact connected to the at least two adjoining source/drain regions.

In another embodiment, a semiconductor device includes a first asymmetrical source/drain region merged with a second asymmetrical source/drain region, and an extended source/drain contact connected to the first asymmetrical source/drain region and the second asymmetrical source/drain region. The semiconductor device further includes at least two isolation structures disposed on opposite sides of the first asymmetrical source/drain region.

In yet another embodiment, a method includes forming a first asymmetrical source/drain region and a second asymmetrical source/drain region merged with the first asymmetrical source/drain region, and forming at least two isolation structures, where the first asymmetrical source/drain region is disposed between the at least two isolation structures, and where the second asymmetrical source/drain region is not disposed between the at least two isolation structures. The method further includes forming an extended source/drain contact connected to the first asymmetrical source/drain region and the second asymmetrical source/drain region.

These and other features and advantages of embodiments described herein will become more apparent from the accompanying drawings and the following detailed description.

### BRIEF DESCRIPTION OF THE DRAWINGS

FIG. 1 depicts a top view of a semiconductor structure indicating X1, X2, Y1, and Y2 cross-section locations on which the cross-sectional views of FIGS. 2A-4D are based.

FIG. 2A depicts a first cross-sectional view of the semiconductor structure corresponding to line X1 of FIG. 1 during an intermediate step of a method of fabricating a nanosheet transistor structure, according to an illustrative embodiment.

FIG. 2B depicts a second cross-sectional view of the semiconductor structure of FIG. 1 corresponding to line X2 during the intermediate step of the method of fabricating the nanosheet transistor structure, according to an illustrative embodiment.

FIG. 2C depicts a third cross-sectional view of the semiconductor structure corresponding to line Y1 of FIG. 1 during the intermediate step of the method of fabricating the nanosheet transistor structure, according to an illustrative embodiment.

FIG. 2D depicts a fourth cross-sectional view of the semiconductor structure corresponding to line Y2 of FIG. 1 during the intermediate step of the method of fabricating the nanosheet transistor structure, according to an illustrative embodiment.

FIG. 3A depicts a first cross-sectional view of the semiconductor structure corresponding to line X1 of FIG. 1 following a source/drain region cut process, according to an illustrative embodiment.

FIG. 3B depicts a second cross-sectional view of the semiconductor structure corresponding to line X2 of FIG. 1 following the source/drain region cut process, according to an illustrative embodiment.

FIG. 3C depicts a third cross-sectional view of the semiconductor structure corresponding to line Y1 of FIG. 1 following the source/drain region cut process, according to an illustrative embodiment.

FIG. 3D depicts a fourth cross-sectional view of the semiconductor structure corresponding to line Y2 of FIG. 1 following the source/drain region cut process, according to an illustrative embodiment.

FIG. 4A depicts a first cross-sectional view of the semiconductor structure corresponding to line X1 of FIG. 1 following inter-layer dielectric (ILD) layer formation and a planarization process, according to an illustrative embodiment.

FIG. 4B depicts a second cross-sectional view of the semiconductor structure corresponding to line X2 of FIG. 1 following the ILD layer formation and the planarization process, according to an illustrative embodiment.

FIG. 4C depicts a third cross-sectional view of the semiconductor structure corresponding to line Y1 of FIG. 1 following the ILD layer formation and the planarization process, according to an illustrative embodiment.

FIG. 4D depicts a fourth cross-sectional view of the semiconductor structure corresponding to line Y2 of FIG. 1 following the ILD layer formation and the planarization process, according to an illustrative embodiment.

FIG. 5 depicts a top view of the semiconductor structure indicating X1, X2, Y1, and Y2 cross-section locations on which the cross-sectional views of FIGS. 6A-6D are based.

FIG. 6A depicts a first cross-sectional view of the semiconductor structure corresponding to line X1 of FIG. 5 following formation of isolation structures, according to an illustrative embodiment.

FIG. 6B depicts a second cross-sectional view of the semiconductor structure corresponding to line X2 of FIG. 5 following the formation of the isolation structures, according to an illustrative embodiment.

FIG. 6C depicts a third cross-sectional view of the semiconductor structure corresponding to line Y1 of FIG. 5 following the formation of the isolation structures, according to an illustrative embodiment.

FIG. 6D depicts a fourth cross-sectional view of the semiconductor structure corresponding to line Y2 of FIG. 5 following the formation of the isolation structures, according to an illustrative embodiment.

FIG. 7 depicts a top view of the semiconductor structure indicating X1, X2, Y1, and Y2 cross-section locations on which the cross-sectional views of FIGS. 8A-8D are based.

FIG. 8A depicts a first cross-sectional view of the semiconductor structure corresponding to line X1 of FIG. 7 following dummy gate layer removal and a replacement metal gate (RMG) process, according to an illustrative embodiment.

FIG. 8B depicts a second cross-sectional view of the semiconductor structure corresponding to line X2 of FIG. 7 following the dummy gate layer removal and the RMG process, according to an illustrative embodiment.

FIG. 8C depicts a third cross-sectional view of the semiconductor structure corresponding to line Y1 of FIG. 7 following the dummy gate layer removal and the RMG process, according to an illustrative embodiment.

FIG. 8D depicts a fourth cross-sectional view of the semiconductor structure corresponding to line Y2 of FIG. 7 following the dummy gate layer removal and the RMG process, according to an illustrative embodiment.

FIG. 9 depicts a top view of the semiconductor structure indicating X1, X2, Y1, and Y2 cross-section locations on which the cross-sectional views of FIGS. 10A-10D are based.

FIG. 10A depicts a first cross-sectional view of the semiconductor structure corresponding to line X1 of FIG. 9 following middle-of-line (MOL) contact formation, according to an illustrative embodiment.

FIG. 10B depicts a second cross-sectional view of the semiconductor structure corresponding to line X2 of FIG. 9 following the MOL contact formation, according to an illustrative embodiment.

FIG. 10C depicts a third cross-sectional view of the semiconductor structure corresponding to line Y1 of FIG. 9 following the MOL contact formation, according to an illustrative embodiment.

FIG. 10D depicts a fourth cross-sectional view of the semiconductor structure corresponding to line Y2 of FIG. 9 following the MOL contact formation, according to an illustrative embodiment.

FIG. 11 depicts a top view of the semiconductor structure indicating X1, X2, Y1, and Y2 cross-section locations on which the cross-sectional views of FIGS. 12A-12D are based.

FIG. 12A depicts a first cross-sectional view of the semiconductor structure corresponding to line X1 of FIG. 11 following formation of a via layer and a metallization layer, according to an illustrative embodiment.

FIG. 12B depicts a second cross-sectional view of the semiconductor structure corresponding to line X2 of FIG. 11 following formation of the via layer and the metallization layer, according to an illustrative embodiment.

FIG. 12C depicts a third cross-sectional view of the semiconductor structure corresponding to line Y1 of FIG. 11 following formation the via layer and the metallization layer, according to an illustrative embodiment.

FIG. 12D depicts a fourth cross-sectional view of the semiconductor structure corresponding to line Y2 of FIG. 11 following formation the via layer and the metallization layer, according to an illustrative embodiment.

FIG. 13 depicts a top view of a semiconductor structure having a conventional contact structure.

### DETAILED DESCRIPTION

Illustrative embodiments may be described herein in the context of illustrative methods for forming a contact structure for an isolated source/drain region, along with illustrative apparatus, systems, and devices formed using such methods. However, it is to be understood that embodiments described herein are not limited to the illustrative methods, apparatus, systems, and devices but instead are more broadly applicable to other suitable methods, apparatus, systems, and devices.

It is to be understood that the various features shown in the accompanying drawings are schematic illustrations that are not necessarily drawn to scale. Moreover, the same or similar reference numbers are used throughout the drawings to denote the same or similar features, elements, or structures, and thus, a detailed explanation of the same or similar features, elements, or structures will not be repeated for each of the drawings. Further, the terms “exemplary” and “illustrative” as used herein mean “serving as an example, instance, or illustration.” Any embodiment or design described herein as “exemplary” or “illustrative” is not to be construed as preferred or advantageous over other embodiments or designs.

A FET is a transistor having a source, a gate, and a drain, and having action that depends on the flow of carriers (electrons or holes) along a channel that runs between the source and drain. Current through the channel between the source and drain may be controlled by a transverse electric field under the gate.

FETs are widely used for switching, amplification, filtering, and other tasks. FETs include metal-oxide-semiconductor (MOS) FETs (MOSFETs). Complementary MOS (CMOS) devices are widely used, where both n-type and p-type transistors (nFET and pFET) are used to fabricate logic and other circuitry. Source and drain regions of a FET are typically formed by adding dopants to target regions of a semiconductor body on either side of a channel, with the gate being formed above the channel. The gate includes a gate dielectric over the channel and a gate conductor over the gate dielectric. The gate dielectric is an insulator material that prevents large leakage current from flowing into the channel when voltage is applied to the gate conductor while allowing applied gate voltage to produce a transverse electric field in the channel.

Various techniques may be used to reduce the size of FETs. One technique is through the use of fin-shaped channels in fin field-effect transistors (FinFET). Before the advent of FinFET arrangements, CMOS devices were typically substantially planar along the surface of the semiconductor substrate, with the exception of the FET gate disposed over the top of the channel. FinFETs utilize a vertical channel structure, increasing the surface area of the channel exposed to the gate. Thus, in FinFET structures, the gate can more effectively control the channel, as the gate extends over more than one side or surface of the channel. In some FinFET arrangements, the gate encloses three surfaces of the three-dimensional channel, rather than being disposed over just the top surface of a traditional planar channel.

Another technique useful for reducing the size of FETs is through the use of stacked nanosheet channels formed over a semiconductor substrate. Stacked nanosheets may be two-dimensional nanostructures, such as sheets having a thickness range on the order of 1 to 20 nanometers (nm). Nanosheets and nanowires are viable options for scaling to 7 nm and beyond. A general process flow for forming a nanosheet stack involves selectively removing sacrificial layers, which may be formed of silicon germanium (SiGe), between sheets of channel material, which may be formed of silicon (Si).

For continued scaling (e.g., to 2.5 nm and beyond), next-generation stacked FET devices may be used. Next-generation stacked FET devices provide a complex gate-all-around (GAA) structure. Conventional GAA FETs, such as nanosheet FETs, may stack multiple p-type nanowires or nanosheets on top of each other in one device, and may stack multiple n-type nanowires or nanosheets on top of each other in another device. Next-generation stacked FET structures provide improved track height scaling, leading to structural gains (e.g., such as 30-40% structural gains for different types of devices, such as logic devices, static random-access memory (SRAM) devices, etc.). In next-generation stacked FET structures, n-type and p-type nanowires or nanosheets are stacked on each other, eliminating n-to-p separation bottlenecks and reducing the device area footprint. Forksheet devices, which are also based on GAA architecture, generally comprise channels separated by a dielectric bar. As non-limiting examples, the dielectric bar can separate sets of n-type channels, sets of p-type channels, or a set of n-type channels and a set of p-type channels.

As discussed above, various techniques may be used to reduce the size of FETs, including through the use of fin-shaped channels in FinFET devices, through the use of stacked nanosheet channels formed over a semiconductor substrate, next-generation complementary FET (CFET) devices, and forksheet FET devices.

Although embodiments described herein are discussed in connection with nanosheet stacks, the embodiments are not necessarily limited thereto, and may similarly apply to nanowire stacks.

Conventional techniques for forming semiconductor devices with tightly spaced metal tracks present significant challenges as technology advances towards smaller nodes. For example, tight tip-to-tip (T2T) spacing between metal tracks can lead to increased capacitance and reliability issues. Furthermore, conventional techniques often require complex wiring schemes, such as dividing a single metal track into two parts, where one part connects to a gate contact and the other part to a source/drain contact. Such techniques frequently result in routing congestion and can prevent stringent pitch requirements from being achieved.

Some embodiments described herein provide a semiconductor structure with an extended source/drain contact over a pair of merged asymmetric source/drain regions, disposed between isolation structures (e.g., double diffusion break regions). Such embodiments can provide enhanced flexibility and reliability in wiring schemes relative to conventional techniques. For example, the extended source/drain contact provides a more robust connection without increasing capacitance, making it particularly advantageous for advanced nodes and backside power delivery network architectures. Additionally, some asymmetric source/drain region configurations described herein can facilitate easier routing of contacts to various metal tracks, thereby reducing the complexities and challenges associated with tight T2T spacing in metallization layers. Moreover, the merged asymmetric source/drain regions provide a stronger contact interface, thereby improving overall device performance and reliability.

The term “asymmetric source/drain regions” generally refers to source/drain regions that differ in size and/or geometry. For instance, in a pFET or nFET, the source region may be larger than the drain region and may possibly extend into an adjacent active area. In some embodiments, this asymmetry can enhance routing flexibility and congestion such as by facilitating connection with other components (e.g., different metal tracks).

Detailed embodiments of transistor structures and methods are disclosed herein. The method steps described below do not form a complete process flow for manufacturing integrated circuits, such as semiconductor devices. The present embodiments can be practiced in conjunction with the integrated circuit fabrication techniques currently used in the art and only so much of the commonly practiced process steps are included as are necessary for an understanding of the described embodiments. The figures represent cross-section portions of a semiconductor structure after fabrication and are not drawn to scale, but instead are drawn to illustrate the features of the described embodiments. Specific structural and functional details disclosed herein are not intended to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on” or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

It will be understood that, although the terms first, second, etc., may be used herein to describe various elements, these elements should not be limited by these terms. These terms are only used to distinguish one element from another element. Thus, a first element discussed below could be termed a second element without departing from the scope of the present concept.

As used herein, “height” refers to a vertical size of an element (e.g., a layer, trench, hole, opening, etc.) in the cross-sectional views measured from a bottom surface to a top surface of the element, and/or measured with respect to a surface on which the element is located. Conversely, a “depth” refers to a vertical size of an element (e.g., a layer, trench, hole, opening, etc.) in the cross-sectional views measured from a top surface to a bottom surface of the element. Terms such as “thick”, “thickness”, “thin” or derivatives thereof may be used in place of “height” where indicated.

As used herein, “width” or “length” refers to a size of an element (e.g., a layer, trench, hole, opening, etc.) in the drawings measured from a side surface to an opposite surface of the element. Terms such as “thick”, “thickness”, “thin” or derivatives thereof may be used in place of “width” or “length” where indicated.

In the interest of not obscuring the presentation of the embodiments of the present disclosure, in the following detailed description, some of the processing steps, materials, or operations that are known in the art may have been combined together for presentation and for illustration purposes and in some instances may not have been described in detail. Additionally, for brevity and maintaining a focus on distinctive features of elements of the present disclosure, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present disclosure.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale. In addition, for ease of explanation, one or more layers, structures, and regions of a type commonly used to form semiconductor devices or structures may not be explicitly shown in a given drawing. This does not imply that any layers, structures, and regions not explicitly shown are omitted from the actual semiconductor structures.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

The term “sacrificial” as used herein generally refers to a placeholder feature that will be removed to define a new or different feature.

The term “substrate” as used herein may refer to material that provides a support structure to features in or on top of the substrate material. As used herein, there may be more than one substrate present in an embodiment shown. Also, since embodiments below are generally shown in cross-section, it should be understood that a substrate for a layer with patterned features may not be visible in the view so as to highlight the features for the layer.

In general, the various processes used to form a semiconductor chip fall into four general categories, namely, film deposition, removal/etching, semiconductor doping, and patterning/lithography. Deposition is any process that grows, coats, or otherwise transfers a material onto the wafer. Available technologies include but are not limited to physical vapor deposition (“PVD”), chemical vapor deposition (“CVD”), electrochemical deposition (“ECD”), molecular beam epitaxy (“MBE”) and more recently, atomic layer deposition (“ALD”) among others. Another deposition technology is plasma enhanced chemical vapor deposition (“PECVD”), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. The patterns created by lithography or photolithography typically are used to define or protect selected surfaces and portions of the semiconductor structure during subsequent etch processes.

Removal is any process such as etching or chemical-mechanical planarization (“CMP”) that removes material from the wafer. Examples of etch processes include either wet (e.g., chemical) or dry etch processes. One example of a removal process or dry etch process is ion beam etching (“IBE”). In general, IBE (or ion milling) refers to a dry plasma etch method that utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry etch process is reactive ion etching (“RIE”). In general, RIE uses chemically reactive plasma to remove material deposited on wafers. High-energy ions from the RIE plasma attack the wafer surface and react with the surface material(s) to remove the surface material(s).

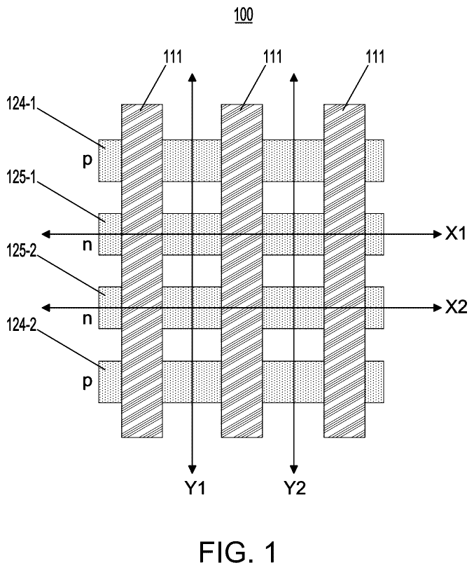

An example of a method for forming a semiconductor device is now described with reference to FIGS. 1-12D.

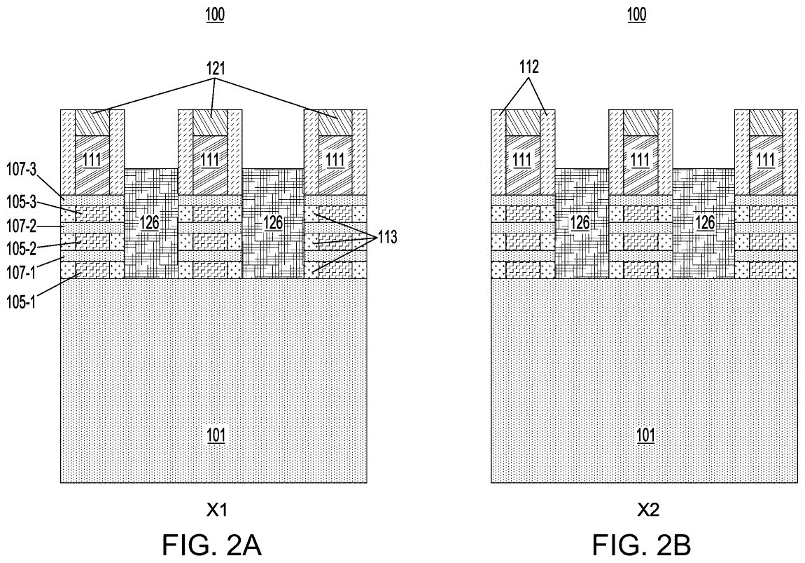

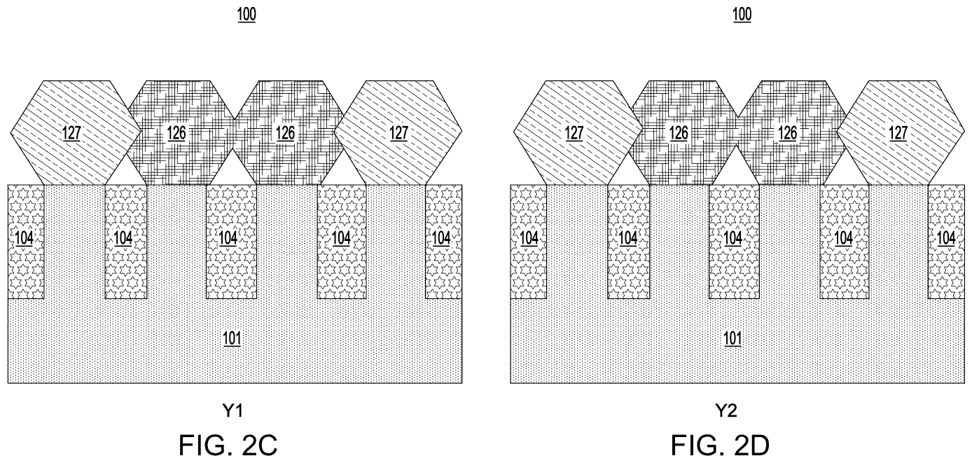

FIG. 1 depicts a top view of a semiconductor structure 100 indicating X1, X2, Y1, and Y2 cross-section locations on which the cross-sectional views of FIGS. 2A-4D are based. Referring also to the cross-sectional views in FIGS. 2A-2D, these figures depict the semiconductor structure 100 during an intermediate fabrication step following patterning of first active regions 124-1 and 124-2 (collectively “first active regions 124”) and second active regions 125-1 and 125-2 (collectively “second active regions 125”), formation of isolation regions 104 (e.g., shallow trench isolation (STI) regions), dummy gate portions 111, gate spacers 112, stacked structures comprising sacrificial layers 105-1, 105-2, and 105-3 (collectively “sacrificial layers 105”) and channel layers 107-1, 107-2, and 107-3 (collectively “channel layers 107”), inner spacers 113, a hardmask (HM) layer 121, and source/drain regions 126 and 127.

In some embodiments, the first active regions 124 and the second active regions 125 may correspond to source/drain regions of respective transistors. For example, the first active regions 124 can correspond to the source/drain regions 126 of one or more p-type transistors, and the second active regions 125 can correspond to the source/drain regions 127 of one or more n-type transistors.

In illustrative embodiments, the sacrificial layers 105 comprise SiGe, and the channel layers 107 comprise silicon (Si). In an illustrative embodiment, the sacrificial layers 105 comprise a germanium concentration of approximately 25% (for example, SiGe 25), but the embodiments are not necessarily limited to SiGe25 for the sacrificial layers 105.

While three sacrificial layers 105 and three channel layers 107 are shown, embodiments described herein are not necessarily limited to the shown number of sacrificial layers 105 and channel layers 107, and there may be more or less layers in the same alternating configuration depending on design constraints. The sacrificial layers 105, as described further herein, are eventually removed, and replaced by gate structures.

The sacrificial layers 105 and the channel layers 107 are epitaxially grown on a semiconductor substrate 101. The terms “epitaxial growth and/or deposition” and “epitaxially formed and/or grown,” mean the growth of a semiconductor material (crystalline material) on a deposition surface of another semiconductor material (crystalline material), in which the semiconductor material being grown (crystalline over layer) has substantially the same crystalline characteristics as the semiconductor material of the deposition surface (seed material). In an epitaxial deposition process, the chemical reactants provided by the source gases are controlled, and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed.

The semiconductor substrate 101 may be formed of any suitable semiconductor material, including various silicon-containing materials such as Si, SiGe, silicon germanium carbide (SiGeC), silicon carbide (SiC), and multi-layers thereof. Although silicon is the predominantly used semiconductor material in wafer fabrication, alternative semiconductor materials can be employed as additional layers such as, but not limited to, germanium (Ge), gallium arsenide (GaAs), gallium nitride (GaN), SiGe, cadmium telluride (CdTe), and zinc selenide (ZnSe).

As used herein, “frontside” or “first side” refers to a side on top of the semiconductor substrate 101 and/or in front of, on top of, or in an upward direction from the stacked gate and channel layers of the transistors in the orientation shown in the cross-sectional figures. As used herein, “backside” or “second side” refers to a side below the semiconductor substrate 101 and/or behind, below, or in a downward direction from the stacked gate and channel layers of the transistors in the orientation shown in the cross-sectional figures (for example, opposite the “frontside”).

The isolation regions 104 are formed between the stacked structures comprising the sacrificial layers 105 and the channel layers 107, and the semiconductor substrate 101. In illustrative embodiments, the isolation regions 104 can comprise a dielectric material. The dielectric material may comprise, for example, silicon nitride (SiN), silicon oxynitride (SiON), silicon-carbon-nitride (SiCN), boron nitride (BN), silicon boron nitride (SiBN), silicoboron carbonitride (SiBCN), silicon oxycarbonitride (SiOCN), silicon oxide (SiOx), and combinations thereof, and is deposited using deposition techniques such as, for example, chemical vapor deposition (CVD), plasma enhanced CVD (PECVD), radio-frequency CVD (RFCVD), physical vapor deposition (PVD), atomic layer deposition (ALD), molecular beam deposition (MBD), pulsed laser deposition (PLD), and/or liquid source misted chemical deposition (LSMCD).

In illustrative embodiments, the source/drain regions 126 and 127 can be epitaxially grown from the exposed portions of the semiconductor substrate 101. In the case of nFETs, the source/drain regions 126 and 127 can comprise silicon doped with n-type dopants including, for example, phosphorus (P), arsenic (As) and antimony (Sb). In the case of pFETs, the source/drain regions 126 and 127 can comprise silicon doped with p-type dopants including, for example, boron (B), boron fluoride (BF₂), gallium (Ga), indium (In), and thallium (Tl).

In the example shown in FIGS. 2A-2D, two of the source/drain regions 126 are disposed between the source/drain regions 127 along the Y1 and Y2 cross-sectional views and between the stacked structures comprising the sacrificial layers 105 and the channel layers 107 along the X1 and X2 cross-sectional views.

The dummy gate portions 111 are formed on the uppermost channel layer 107-3, and around the stacked structures comprising the sacrificial layers 105 and the channel layers 107, as shown. The dummy gate portions 111 include but are not limited to an amorphous silicon (a-Si) layer. The dummy gate portions 111 are deposited using deposition techniques such as, for example, CVD, PECVD, RFCVD, PVD, ALD, MBD, PLD, LSMCD, sputtering, and/or plating, followed by a planarization process, such as CMP, and lithography and etching steps to remove excess dummy gate material, and pattern the deposited layer.

The HM layer 121 is formed on the dummy gate portions 111 using any conventional deposition technique such as PVD, ALD, CVD, etc., followed by a planarization step such as a CMP process. The HM layer 121 can be formed of any suitable material such as, for example, amorphous silicon, or another suitable material.

The gate spacers 112 are formed on sides of the HM layer 121 and dummy gate portions 111 by one or more of the deposition techniques noted in connection with the deposition of the dummy gate material. The spacer material can comprise, for example, one or more dielectrics, such as but not limited to, SiN, SiON, SiOC, SiCN, BN, SiBN, SiBCN, SiOCN, SiOₓ, and combinations thereof. According to an embodiment, the HM layer 121 and gate spacers 112 can be the same material or different materials. The gate spacers 112 can be formed by any suitable techniques such as deposition followed by directional etching. Deposition may include, but is not limited to, ALD or CVD. Directional etching may include but is not limited to, reactive ion etching (RIE).

Due to, for example, germanium in the sacrificial layers 105, lateral etching of the sacrificial layers 105 can be performed selective to the channel layers 107, such that the side portions of the sacrificial layers 105 can be removed to create vacant areas to be filled in by the inner spacers 113. The material of the inner spacers 113 can comprise, but is not necessarily limited to, a nitride, such as, SiN, SiON, SiCN, BN, SiBN, SiBCN, or SiOCN. Like the gate spacers 112, the inner spacers 113 can be formed by any suitable techniques such as deposition followed by directional etching.

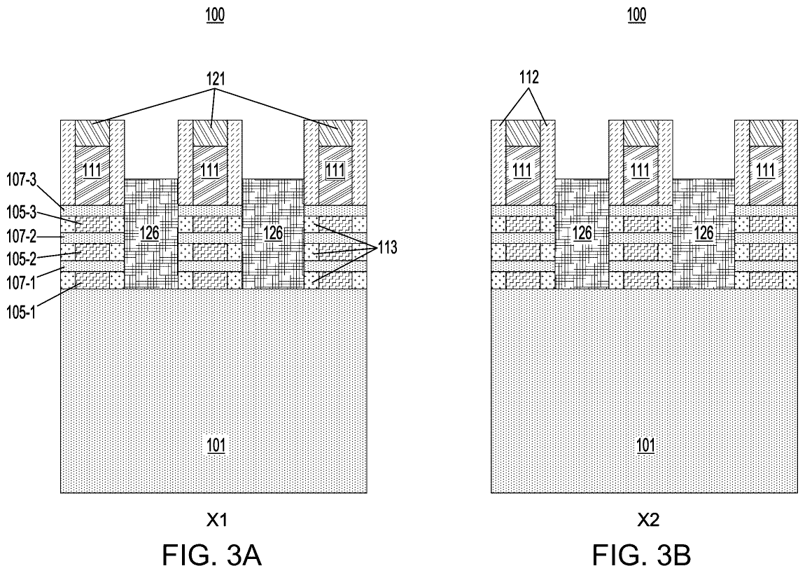

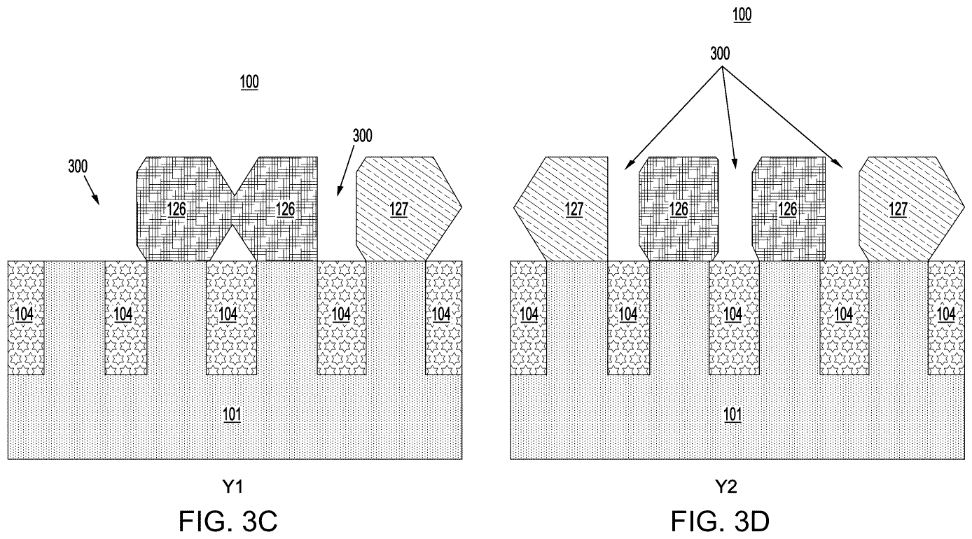

FIGS. 3A-3D depict cross-sectional views of the semiconductor structure 100 following a source/drain region cut process. The source/drain region cut process creates trenches 300 to separate at least some of the source/drain regions 126 and 127. As seen in FIG. 3D, trenches 300 are formed between each pair of adjacent source/drain regions 126 and 127. However, the source/drain cut process leaves some of the source/drain regions 126 and 127 intentionally merged. For example, in FIG. 3C, the source/drain cut process removes one of the source/drain regions 127 and a part of the other source/drain region 127, but the source/drain regions 126 remain merged.

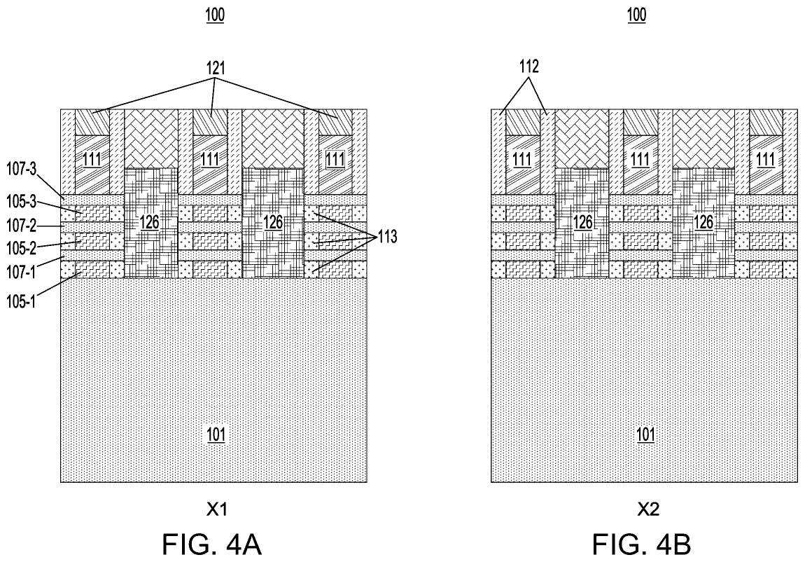

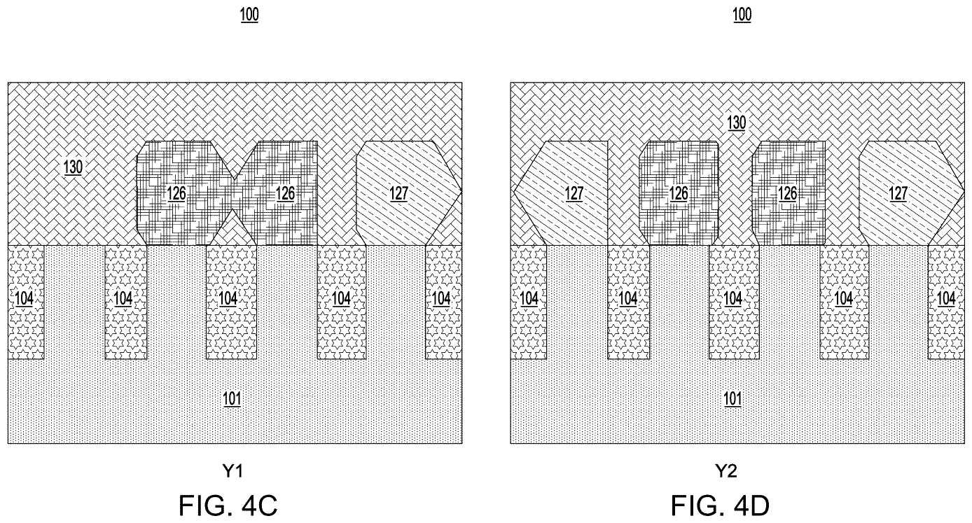

FIGS. 4A-4D depict cross-sectional views of the semiconductor structure 100 corresponding following formation of an ILD layer 130. The ILD layer 130 is deposited to fill in portions on and around the exposed portions of the semiconductor substrate 101, the gate spacers 112, the isolation regions 104, and the source/drain regions 126 and 127. The ILD layer 130 is deposited using deposition techniques such as, for example, CVD, PECVD, RFCVD, PVD, ALD, MBD, PLD, and/or LSMCD, followed by a planarization process, such as CMP, to remove excess portions of the ILD layer 130 deposited on the top surfaces of the HM layer 121 and gate spacers 112. The ILD layer 130 may comprise, for example, SiOx, SiOC, SiOCN, or some other dielectric.

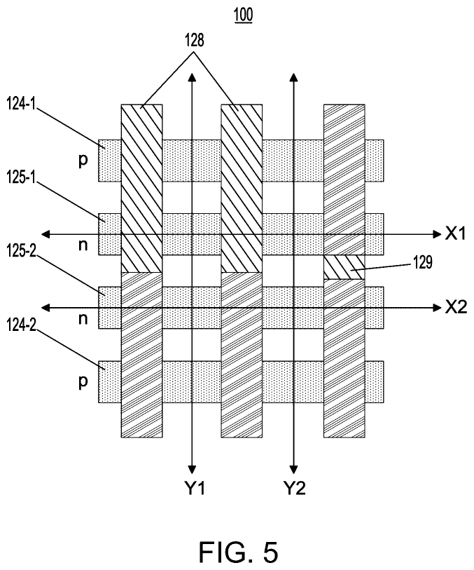

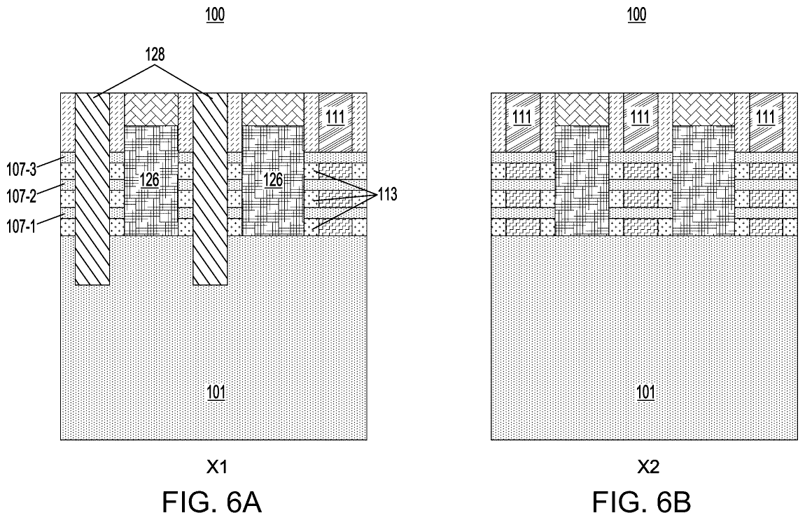

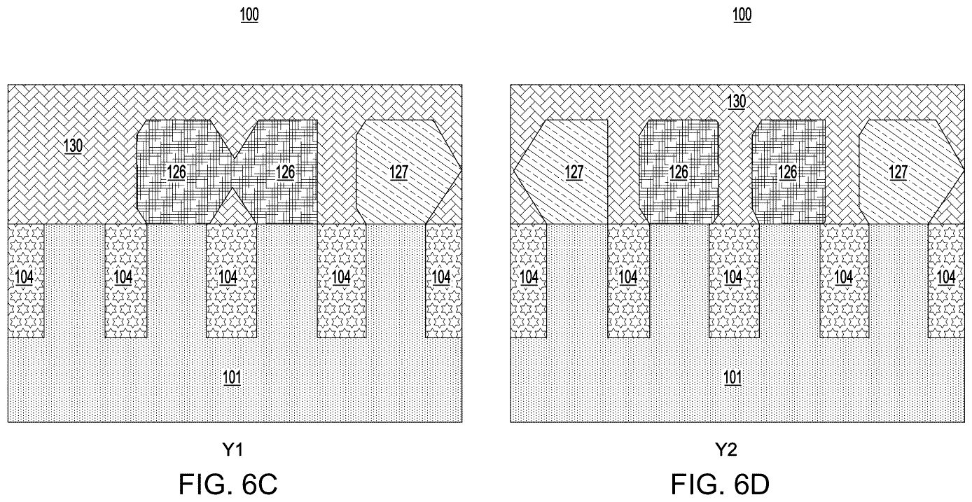

FIG. 5 depicts a top view of the semiconductor structure 100 indicating X1, X2, Y1, and Y2 cross-section locations on which the cross-sectional views of FIGS. 6A-6D are based. Referring also to the cross-sectional views in FIGS. 6A-6D, these figures depict the semiconductor structure 100 following formation of isolation structures 128 and 129. In some embodiments, the isolation structures 129 can be performed using a double diffusion break process. The double diffusion break process can include a mask and patterning process. For example, a dry etch process using RIE or IBE, a wet chemical etch process, or a combination of these etching processes can be performed to remove portions of the HM layer 121, the dummy gate portions 111, and the stacked structures comprising the sacrificial layers 105 and the channel layers 107, and the semiconductor substrate 101 down to a level below the bottom surface of the source/drain regions 126 and 127 to create vacant areas corresponding to where the isolation structures 128 are shown in FIG. 5 and FIG. 6A.

The isolation structures 128 are formed by depositing a dielectric material in the vacant areas using deposition techniques such as, for example, CVD, PECVD, RFCVD, PVD, ALD, MBD, PLD, and/or LSMCD, followed by a planarization process, such as, CMP. The dielectric material of the isolation structures 128 may comprise, but is not necessarily limited to, SiN, SiC, SiON, SiOC, SiCN, BN, SiBN, SiBCN, SiOCN, SiOₓ, or some other dielectric. In some embodiments, the process for forming the isolation structures 128 corresponds to a double diffusion break process.

The isolation structure 129 can be formed using a gate cut process. The gate cut process can include one or more etching processes that remove parts of the HM layer 121, the dummy gate portions 111, the stacked structures comprising the sacrificial layers 105 and the channel layers 107, and the semiconductor substrate 101 to create vacant areas corresponding to where the isolation structure 129 is shown in FIG. 5 and FIG. 6A. The isolation structure 129 can be formed using similar techniques and materials as the isolation structures 128, for example.

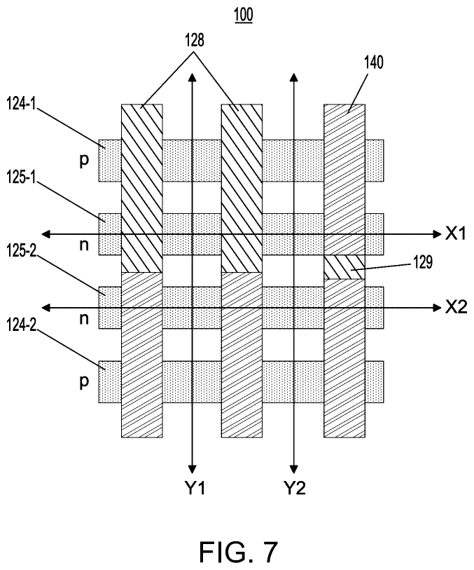

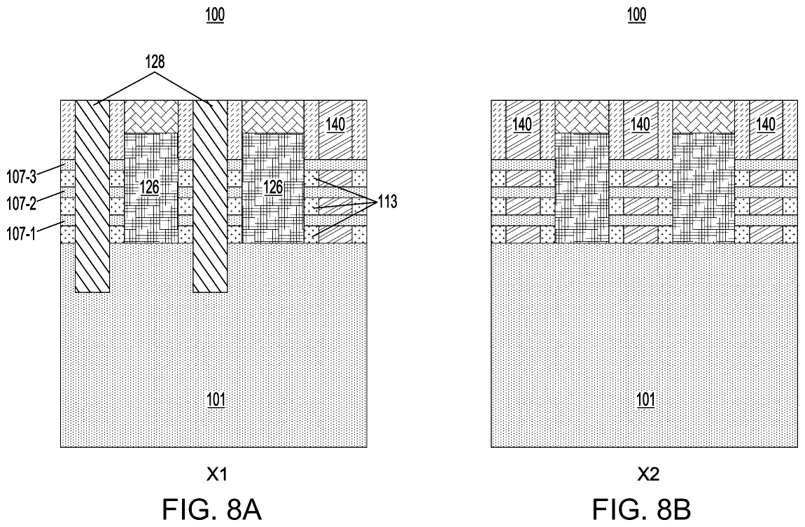

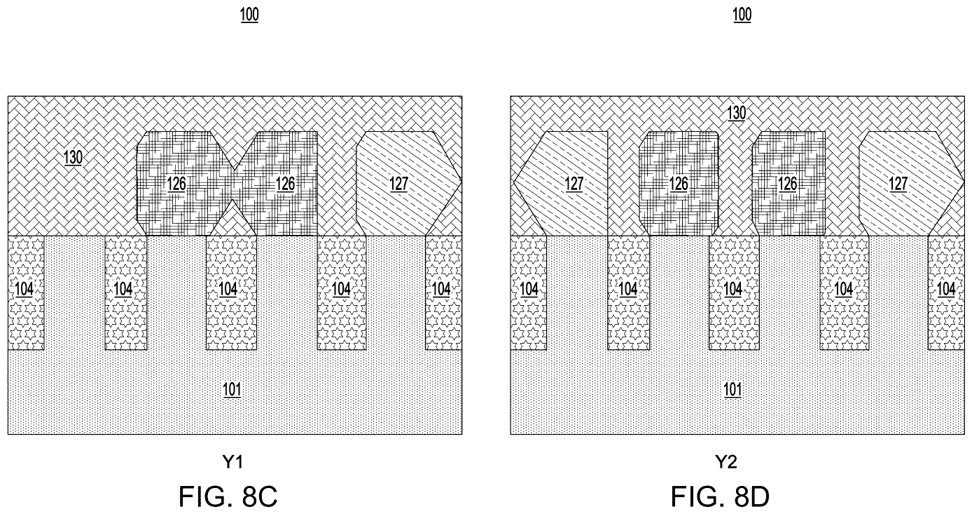

FIG. 7 depicts a top view of the semiconductor structure 100 indicating X1, X2, Y1, and Y2 cross-section locations on which the cross-sectional views of FIGS. 8A-8D are based. Referring also to the cross-sectional views in FIGS. 8A-8D, these figures depict the semiconductor structure 100 following removal of the dummy gate portions 111 and formation of gate structures 140.

The dummy gate portions 111 and the sacrificial layers 105 are selectively removed to create vacant areas, and gate structures 140 are formed in the vacant areas. For example, the dummy gate portions 111 can be selectively removed using hot ammonia to remove a-Si, and the sacrificial layers 105 can be selectively removed with respect to the channel layers 107 using, for example, a dry HCl etch.

Following removal of the dummy gate portions 111 and the sacrificial layers 105, the channel layers 107 are suspended, and the gate structures 140, including, for example, gate and dielectric portions, are formed in the vacant portions left by removal of the dummy gate portions 111 and the sacrificial layers 105. In illustrative embodiments, each gate structure 140 includes a gate dielectric layer such as, for example, a high-K dielectric layer including, but not necessarily limited to, HfO₂ (hafnium oxide), ZrO₂ (zirconium dioxide), hafnium zirconium oxide, Al₂O₃ (aluminum oxide), and Ta₂O₅ (tantalum oxide). Examples of high-k materials also include, but are not limited to, metal oxides such as hafnium silicon oxynitride, lanthanum oxide, lanthanum aluminum oxide, zirconium oxide, zirconium silicon oxide, zirconium silicon oxynitride, tantalum oxide, titanium oxide, barium strontium titanium oxide, barium titanium oxide, strontium titanium oxide, yttrium oxide, aluminum oxide, lead scandium tantalum oxide, and lead zinc niobate.

According to an embodiment, the gate structures 140 each include a metal gate portion including a work-function metal (WFM) layer, including but not necessarily limited to, for a pFET, titanium nitride (TiN), tantalum nitride (TaN) or ruthenium (Ru), and for an nFET, TiN, titanium aluminum nitride (TiAlN), titanium aluminum carbon nitride (TiAlCN), titanium aluminum carbide (TiAlC), tantalum aluminum carbide (TaAlC), tantalum aluminum carbon nitride (TaAlCN) or lanthanum (La) doped TiN, TaN, which can be deposited on the gate dielectric layer. The metal gate portions can also each further include a gate metal layer including, but not necessarily limited to, metals, such as tungsten, cobalt, zirconium, tantalum, titanium, aluminum, ruthenium, copper, metal carbides, metal nitrides, transition metal aluminides, tantalum carbide, titanium carbide, tantalum magnesium carbide, or combinations thereof deposited on the WFM layer and the gate dielectric layer. It should be appreciated that various other materials may be used for the metal gate portions as desired.

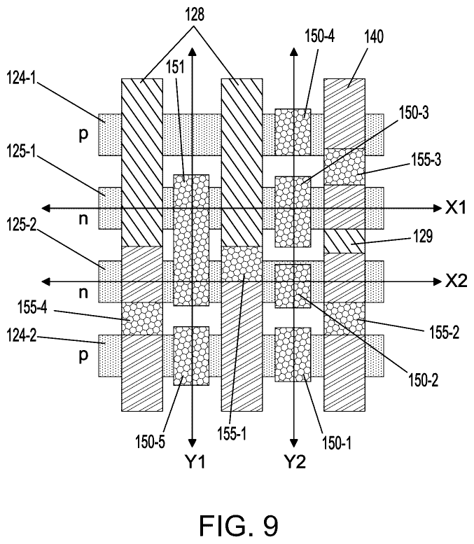

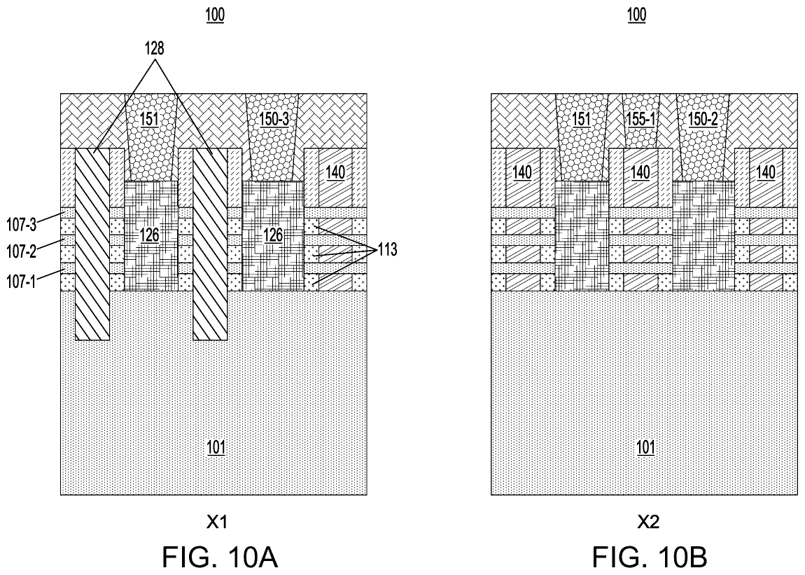

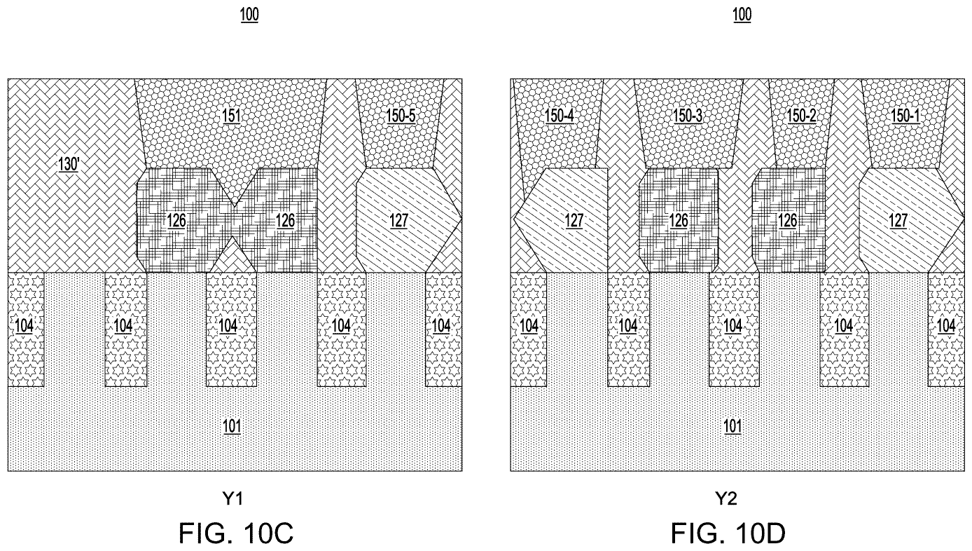

FIG. 9 depicts a top view of the semiconductor structure 100 indicating X1, X2, Y1, and Y2 cross-section locations on which the cross-sectional views of FIGS. 10A-10D are based. Referring also to the cross-sectional views in FIGS. 10A-10D, these figures depict the semiconductor structure 100 following formation of MOL contacts. The MOL contacts include source/drain contacts 150-1 through 150-5 (collectively “source/drain contacts 150”), an extended source/drain contact 151, and gate contacts 155-1, 155-2, 155-3, and 155-4 (collectively gate contacts 155).

In some embodiments, additional ILD material is deposited on the ILD layer 130, thereby forming ILD layer 130′. The source/drain contacts 150 and the extended source/drain contact 151 are formed in the ILD layer 130′ to contact respective top surfaces of the source/drain regions 126 and 127. To form the source/drain contacts 150 and the extended source/drain contact 151, openings are created through portions of the ILD layer 130′, exposing the corresponding portions of the source/drain regions 126 and 127 on which the source/drain contacts 150 and the extended source/drain contact 151 are to be formed. According to an embodiment, masks are formed on parts of the ILD layer 130′, and exposed portions of the ILD layer 130′ corresponding to where the openings are to be formed are removed using, for example, a dry etching process using a RIE or ion beam etch (IBE) process, a wet chemical etch process, or a combination of these etching processes. A dry etch may be performed using a plasma. Such wet or dry etch processes include, for example, IBE by Ar/CHF3 based chemistry.

Metal layers can then be deposited in the openings to form the source/drain contacts 150 and the extended source/drain contact 151. The metal layers may include a silicide layer, such as Ni, Ti, NiPt, etc., a metal adhesion layer such as TiN, and a conductive metal fill layer, such as W, Al, Co, Ru, etc., and can be deposited using, for example, a deposition technique such as CVD, PECVD, RFCVD, PVD, ALD, MBD, PLD, LSMCD, sputtering, and/or plating, followed by planarization processes such as CMP to remove excess portions of the metal layers from on top of the ILD layer 130′.

The process and materials used for forming the gate contacts 155 are similar to those used for forming the source/drain contacts 150.

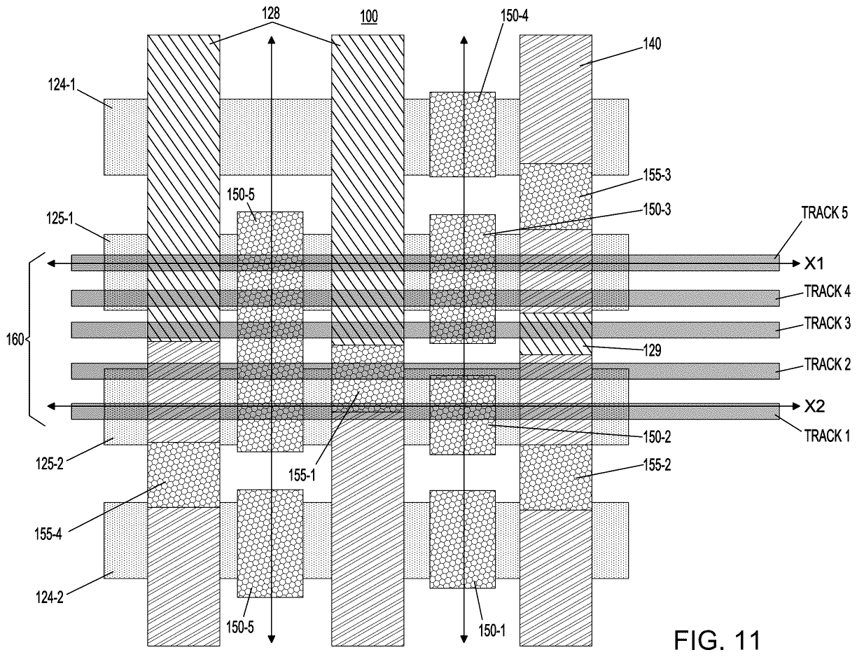

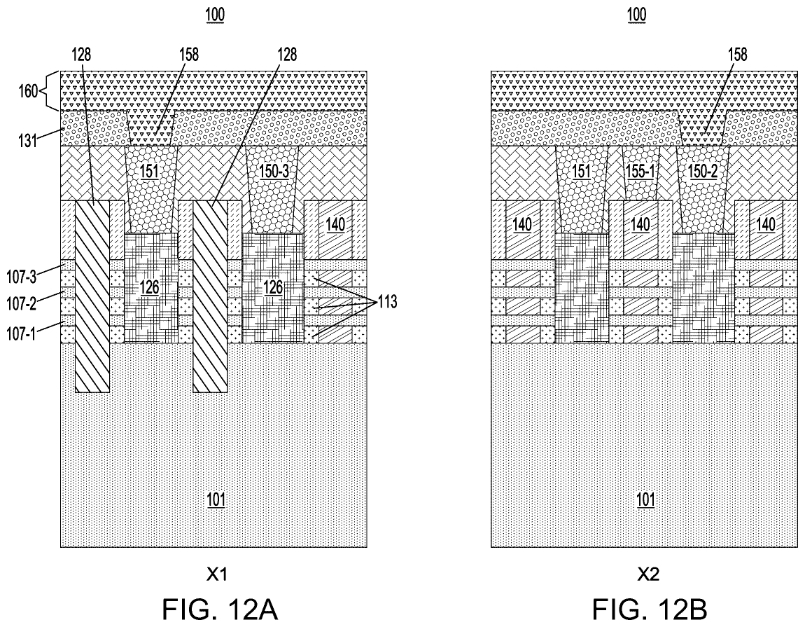

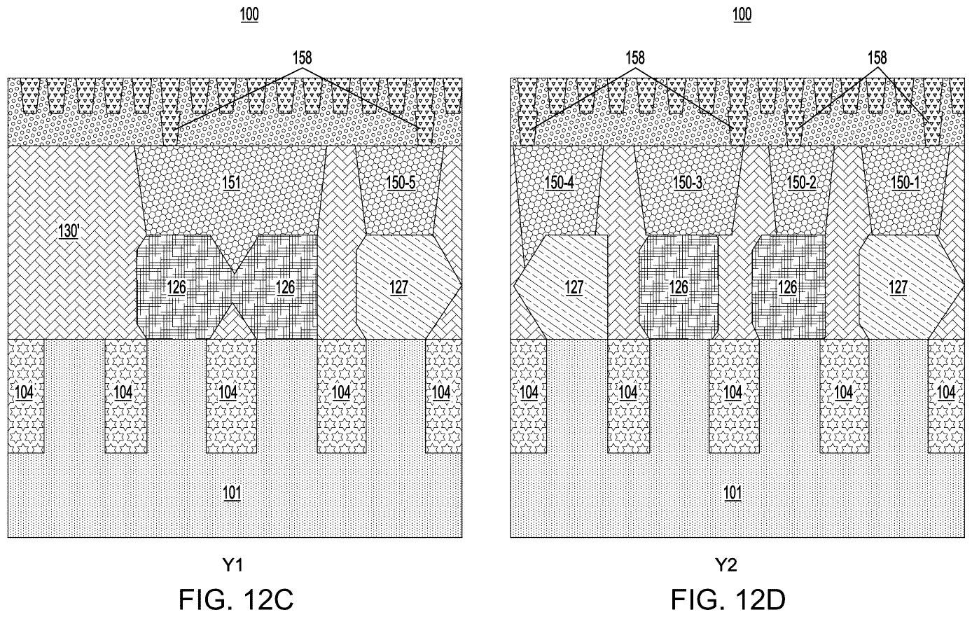

FIG. 11 depicts a top view of the semiconductor structure 100 indicating X1, X2, Y1, and Y2 cross-section locations on which the cross-sectional views of FIGS. 12A-12D are based. Referring also to the cross-sectional views in FIGS. 12A-12D, these figures depict the semiconductor structure 100 following formation of a via layer comprising vias 158 and a metallization layer 160.

In an illustrative embodiment, an additional ILD layer 131 is formed above the ILD layer 130′. The additional ILD layer 131 may be formed using similar techniques and materials as ILD layer 130, for example. The metallization layer 160 is formed in the additional ILD layer 131. The metallization layer 160 can comprise a plurality of tracks. In the example shown in FIG. 11, the metallization layer 160 includes tracks 1 through 5. As shown in FIGS. 12A-12D, the vias 158 extend from the metallization layer 160 to the source/drain contacts 150, the extended source/drain contact 151, and one or more of the gate structures 140. In some embodiments, the metallization layer 160 can be formed by making one or more trenches and filling the trenches with a metal material (e.g., copper (Cu)). As an example, the metal material can be deposited using any suitable deposition technique (e.g., sputtering, and/or plating), followed by a planarization process (e.g., CMP). In at least some embodiments, the vias 158 can be formed using similar techniques and materials to those used for forming the source/drain contacts 150, the extended source/drain contact 151, and the gate contacts 155.

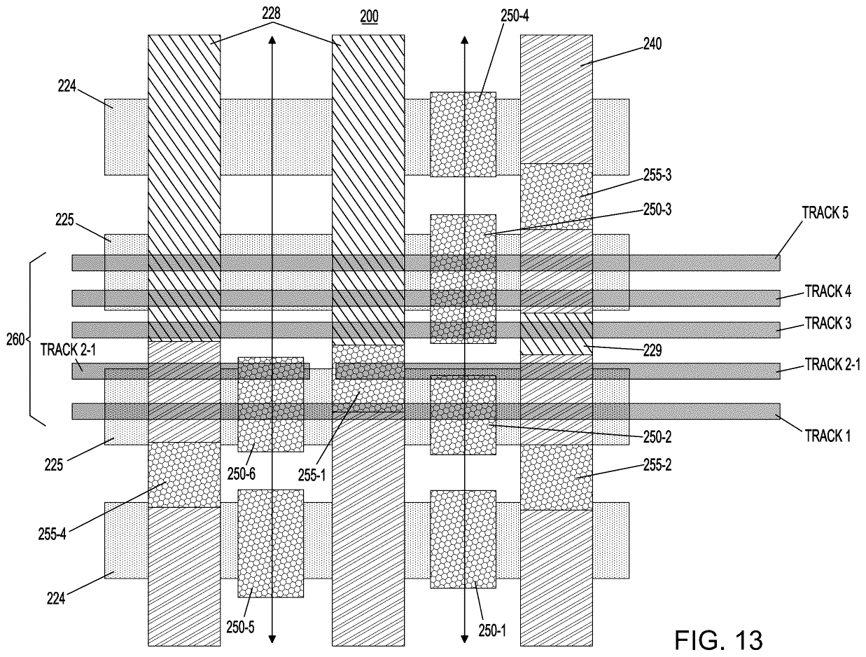

Conventional techniques generally do not have merged source/drain regions with an extended source/drain contact. For example, FIG. 13 depicts a top view of a semiconductor structure 200 having a conventional contact structure. Similar to semiconductor structure 100, the semiconductor structure 200 includes first active regions 224, second active regions 225, isolation structures 228 and 229, gate structures 240, gate contacts 255-1, 255-2, 255-3, and 255-4 (collectively gate contacts 255), and a metallization layer 260. The semiconductor structure 200 also includes source/drain contacts 250-1 through 250-6. In contrast to the semiconductor structure 100 shown in FIG. 11, the semiconductor structure 200 does not include an extended source/drain contact. Track 2 of the metallization layer 260 is divided into two parts (track 2-1 and track 2-2), where gate contact 255-1 is wired to track 2-1 and source/drain contact 250-6 is wired to track 2-2. This can lead to various issues (e.g., increased capacitance and/or reliability issues) as semiconductor technology advances towards smaller nodes, since the spacing between the tracks of the metallization layer 260 also decreases.

The semiconductor structure 100 shown in FIG. 11 provides increased flexibility when wiring the source/drain contacts 150, the extended source/drain contact 151, and the gate contacts 155 to the metallization layer 160 relative to conventional techniques. For example, the source/drain contact 150-2 can be wired to track 1 of the metallization layer 160, and the gate contact 155-1 can be wired to track 2 of the metallization layer 160. Additionally, the extended source/drain contact 151 extends over the source/drain regions 126 that were left merged following the source/drain region cut process described in conjunction with FIGS. 3A-3D, which allows the extended source/drain contact 151 to be wired to track 4 of the metallization layer 160.

The extended source/drain contact 151 provides a reliable connection due to the increased size of the extended source/drain contact 151 and the merged source/drain regions 126, without increasing capacitance. Such embodiments can be particularly useful for advanced nodes where the spacing between metal tracks is often tight. Additionally, for a backside power delivery network (BSPDN) architecture, a hole is required to be drilled from a backside wafer in order to connect the BSPDN to a particular source/drain region. However, it is often challenging to properly align the hole because the size of the source/drain region can be small. The extended source/drain contact 151 addresses this issue by providing a larger margin of error, for example.

Semiconductor devices and methods for forming the same in accordance with the above-described techniques can be employed in various applications, hardware, and/or electronic systems. Suitable hardware and systems for implementing embodiments of the invention may include, but are not limited to, personal computers, communication networks, electronic commerce systems, portable communications devices (e.g., cell and smart phones), solid-state media storage devices, functional circuitry, etc. Systems and hardware incorporating the semiconductor devices are contemplated embodiments of the invention. Given the teachings provided herein, one of ordinary skill in the art will be able to contemplate other implementations and applications of embodiments of the invention.

In some embodiments, the above-described techniques are used in connection with semiconductor devices that may require or otherwise utilize, for example, CMOSs, MOSFETs, and/or FinFETs. By way of non-limiting example, the semiconductor devices can include, but are not limited to CMOS, MOSFET, and FinFET devices, and/or semiconductor devices that use CMOS, MOSFET, and/or FinFET technology.

Various structures described above may be implemented in integrated circuits. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either: (a) an intermediate product, such as a motherboard, or (b) an end product. The end product can be any product that includes integrated circuit chips, ranging from toys and other low-end applications to advanced computer products having a display, a keyboard or other input device, and a central processor.

In one embodiment, a semiconductor device includes at least two adjoining source/drain regions corresponding to at least two adjacent transistor devices, where a first one of the at least two adjoining source/drain regions is disposed between at least two isolation structures. The semiconductor device further includes an extended source/drain contact connected to the at least two adjoining source/drain regions.

In embodiments, the semiconductor device may further include at least one via connected to the at least two adjoining source/drain regions through the extended source/drain contact, where the at least one via is disposed between the at least two isolation structures.

In embodiments, a second one of the at least two adjoining source/drain regions is not disposed between the at least two isolation structures.

In embodiments, the semiconductor device may further include a first metal track disposed at least partially above the first one of the at least two adjoining source/drain regions, where the first metal track is connected to the extended source/drain contact through the at least one via, and a second metal track disposed at least partially above the second one of the at least two adjoining source/drain regions.

In embodiments, the semiconductor device may further include a third metal track connected to a gate contact, where the third metal track is adjacent to the second metal track.

In embodiments, the at least two adjacent transistor devices may include either at least two n-type transistor devices or at least two p-type transistor devices.

In embodiments, the semiconductor device may further include at least one additional source/drain contact, where the at least one additional source/drain contact is connected to one of a plurality of additional source/drain regions.

In embodiments, each of the at least two adjoining source/drain regions may include an asymmetric source/drain region.

In embodiments, the semiconductor device may further include a cut region disposed between the first one of the at least two adjoining source/drain regions and an additional source/drain region.

In embodiments, the additional source/drain region may correspond to one of an n-type transistor device and a p-type transistor device, and the first one of the at least two adjoining source/drain regions may correspond to the other one of the n-type transistor device and the p-type transistor device.

In another embodiment, a semiconductor device includes a first asymmetrical source/drain region merged with a second asymmetrical source/drain region, and an extended source/drain contact connected to the first asymmetrical source/drain region and the second asymmetrical source/drain region. The semiconductor device further includes at least two isolation structures disposed on opposite sides of the first asymmetrical source/drain region.

In embodiments, the semiconductor device may further include at least one via connected to the extended source/drain contact, where the at least one via is disposed between the at least two isolation structures.

In embodiments, the semiconductor device may further include a first metal track connected to the extended source/drain contact through the at least one via, and a second metal track disposed at least partially above the second asymmetrical source/drain region.

In embodiments, the semiconductor device may further include a third metal track connected to a gate contact, where the third metal track is adjacent to the second metal track and disposed at least partially above the second asymmetrical source/drain region.

In embodiments, the semiconductor device may further include a cut region disposed between the second asymmetrical source/drain region and an additional source/drain region.

In embodiments, the second asymmetrical source/drain region is not disposed between the at least two isolation structures.

In embodiments, the at least two isolation structures may correspond to double diffusion break regions.

In embodiments, the semiconductor device may further include one or more additional source/drain contacts, where each of the one or more additional source/drain contacts is smaller than the extended source/drain contact.

In yet another embodiment, a method includes forming a first asymmetrical source/drain region and a second asymmetrical source/drain region merged with the first asymmetrical source/drain region, and forming at least two isolation structures, where the first asymmetrical source/drain region is disposed between the at least two isolation structures, and where the second asymmetrical source/drain region is not disposed between the at least two isolation structures. The method further includes forming an extended source/drain contact connected to the first asymmetrical source/drain region and the second asymmetrical source/drain region.

In embodiments, the method may further include forming at least one via connected to the first asymmetrical source/drain region through the extended source/drain contact, forming a first metal track disposed at least partially above the first asymmetrical source/drain region, where the first metal track is connected to the extended source/drain contact through the at least one via, and forming a second metal track disposed at least partially above the second asymmetrical source/drain region.

It should be understood that the various layers, structures, and regions shown in the figures are schematic illustrations that are not drawn to scale. In addition, for ease of explanation, one or more layers, structures, and regions of a type commonly used to form semiconductor devices or structures may not be explicitly shown in a given figure. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

Moreover, the same or similar reference numbers are used throughout the figures to denote the same or similar features, elements, or structures, and thus, a detailed explanation of the same or similar features, elements, or structures are not repeated for each of the figures. It is to be understood that the terms “approximately” or “substantially” as used herein with regard to thicknesses, widths, percentages, ranges, temperatures, times, and other process parameters, etc., are meant to denote being close or approximate to, but not exactly. For example, the term “approximately” or “substantially” as used herein implies that a small margin of error is present, such as ±5%, preferably less than 2% or 1% or less than the stated amount.

In the description above, various materials, dimensions and processing parameters for different elements are provided. Unless otherwise noted, such materials are given by way of example only and embodiments are not limited solely to the specific examples given. Similarly, unless otherwise noted, all dimensions and process parameters are given by way of example and embodiments are not limited solely to the specific dimensions or ranges given.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
at least two adjoining source/drain regions corresponding to at least two adjacent transistor devices, wherein a first one of the at least two adjoining source/drain regions is disposed between at least two isolation structures; and
an extended source/drain contact connected to the at least two adjoining source/drain regions.

2. The semiconductor device of claim 1, further comprising:
at least one via connected to the at least two adjoining source/drain regions through the extended source/drain contact, wherein the at least one via is disposed between the at least two isolation structures.

3. The semiconductor device of claim 2, wherein a second one of the at least two adjoining source/drain regions is not disposed between the at least two isolation structures.

4. The semiconductor device of claim 3, further comprising:
a first metal track disposed at least partially above the first one of the at least two adjoining source/drain regions, wherein the first metal track is connected to the extended source/drain contact through the at least one via; and
a second metal track disposed at least partially above the second one of the at least two adjoining source/drain regions.

5. The semiconductor device of claim 4, further comprising:
a third metal track connected to a gate contact, wherein the third metal track is adjacent to the second metal track.

6. The semiconductor device of claim 1, wherein the at least two adjacent transistor devices comprise either at least two n-type transistor devices or at least two p-type transistor devices.

7. The semiconductor device of claim 1, further comprising:
at least one additional source/drain contact, wherein the at least one additional source/drain contact is connected to one of a plurality of additional source/drain regions.

8. The semiconductor device of claim 1, wherein each of the at least two adjoining source/drain regions comprises an asymmetric source/drain region.

9. The semiconductor device of claim 1, further comprising:
a cut region disposed between the first one of the at least two adjoining source/drain regions and an additional source/drain region.

10. The semiconductor device of claim 9, wherein the additional source/drain region corresponds to one of an n-type transistor device and a p-type transistor device, and wherein the first one of the at least two adjoining source/drain regions corresponds to the other one of the n-type transistor device and the p-type transistor device.

11. A semiconductor device comprising:
a first asymmetrical source/drain region merged with a second asymmetrical source/drain region;
an extended source/drain contact connected to the first asymmetrical source/drain region and the second asymmetrical source/drain region; and
at least two isolation structures disposed on opposite sides of the first asymmetrical source/drain region.

12. The semiconductor device of claim 11, further comprising:
at least one via connected to the extended source/drain contact, wherein the at least one via is disposed between the at least two isolation structures.

13. The semiconductor device of claim 12, further comprising:
a first metal track connected to the extended source/drain contact through the at least one via; and
a second metal track disposed at least partially above the second asymmetrical source/drain region.

14. The semiconductor device of claim 13, further comprising:
a third metal track connected to a gate contact, wherein the third metal track is adjacent to the second metal track and disposed at least partially above the second asymmetrical source/drain region.

15. The semiconductor device of claim 11, further comprising:
a cut region disposed between the second asymmetrical source/drain region and an additional source/drain region.

16. The semiconductor device of claim 11, wherein the second asymmetrical source/drain region is not disposed between the at least two isolation structures.

17. The semiconductor device of claim 11, wherein the at least two isolation structures correspond to double diffusion break regions.

18. The semiconductor device of claim 11, further comprising:
one or more additional source/drain contacts, wherein each of the one or more additional source/drain contacts is smaller than the extended source/drain contact.

19. A method comprising:
forming a first asymmetrical source/drain region and a second asymmetrical source/drain region merged with the first asymmetrical source/drain region;
forming at least two isolation structures, wherein the first asymmetrical source/drain region is disposed between the at least two isolation structures, and wherein the second asymmetrical source/drain region is not disposed between the at least two isolation structures; and
forming an extended source/drain contact connected to the first asymmetrical source/drain region and the second asymmetrical source/drain region.

20. The method of claim 19, further comprising:
forming at least one via connected to the first asymmetrical source/drain region through the extended source/drain contact;
forming a first metal track disposed at least partially above the first asymmetrical source/drain region, wherein the first metal track is connected to the extended source/drain contact through the at least one via; and
forming a second metal track disposed at least partially above the second asymmetrical source/drain region.
